(19) United States
(12) Patent Application Publication
(10) Pub. No.: US 2004/0165737 A1
(43) Pub. Date: Aug. 26, 2004

(54) Audio compression

(76) Inventor: Donald Martin Monro, Beckington (GB)

Correspondence Address: Roger H Stein, Wallenstein Wagner & Rockey, 53rd Floor, 311 South Wacker Drive, Chicago, IL, 60606-6630, US

(21) Appl. No.: 10/473,649

(22) PCT Filed: Mar. 7, 2002
(86) PCT No.: PCT/GB02/01014

(30) Foreign Application Priority Data
Mar. 30, 2001 (GB) 0108080.3

(51) Int. Cl. H04B 1/64; H03G 5/00

(52) U.S. Cl. 381/106; 381/98; 333/14

(57) ABSTRACT

An audio codec and a method of compressing audio data makes use of a filterbank which automatically adapts itself to changes in the sampling frequency/bit rate to mimic the characteristics of the human auditory system. The algorithm used compares the bandwidth of each sub-band at a given depth with the critical bandwidth. If the critical bandwidth is less than the bandwidth of the sub-band, then the sub-band is split into two at the next level, and the process is repeated until the bandwidth of every sub-band is less than the critical bandwidth at the corresponding frequency. The codec thus automatically adapts itself to changes in sampling frequency/bit rate, which is particularly advantageous when very low bandwidths are in use.

The present invention relate to audio compression, and in particular to methods of and apparatus for compression of audio signals using an auditory filterbank which mimics the response of the human ear.

Analogue audio signals such as those of speech or music are almost always represented digitally by repeatedly sampling the waveform and representing the waveform by the resultant quantized samples. This is known as Pulse Code Modulation (PCM). PCM is typically used without compression in certain high-bandwidth audio devices (such as CD players), but compression is normally essential where the digitised audio signal has to be transmitted across a communications medium such as a computer or telephone network. Compression also of course reduces the storage requirements, for example where an audio sample needs to be stored on the hard disk drive of a computer.

Numerous audio compression algorithms are known, the general principles being that redundancy in the data-stream should be reduced and that information should not be transmitted which will, on receipt, be inaudible to the listener. One popular approach is to use sub-band coding, which attempts to mimic the frequency response of the human ear by splitting the audio spectrum up into a large number of different frequency bands, and then quantising signals within those bands independently. The basis of such an approach is that the frequency response of the human ear can be approximated by a band-pass filterbank, consisting of overlapping band-pass filters (“critical-band filters”). The filters are nearly symmetric on a linear frequency scale, with very sharp skirts. The filter bandwidth is roughly constant at about 100 Hz for low centre frequencies, while higher frequencies the critical bandwidth increases with frequency. It is usually said that twenty five critical bands are required to cover frequencies to 20 kHz.

In a typical transform coder, each of the sub-bands has its own defined masking threshold. The coder usually uses a Fast Fourier Transform (FFT) to detect differences between the perceptually critical audible sounds, the non-perceptually critical sounds and the quantization noise present in the system, and then adjusts the masking threshold, according to the preset perceptual model, to suit. Once filtered, the output data from each of the sub-bands is re-quantized with just enough bit resolution to maintain adequate headroom between the quantization noise and the masking threshold for each band.

A useful review of current audio compression techniques may be found in Digital Audio Data Compression, F Wylie, Electronics & Communication Engineering Journal, February 1995, pages 5 to 10. Further details of the masking process are described in Auditory Masking and MPEG-1 Audio Compression, E Ambikairajah, A G Davies and W T K Wong, Electronics & Communication Engineering Journal, August 1997, pages 165 to 175.

A large number of auditory filterbanks have been devised by different researchers some of which map more closely than others onto the measured “critical bands” of the human auditory system. When writing a new codec the author will either choose one of the existing filterbanks for use with it or, alternatively, may devise a new filterbank optimised for the particular circumstances in which the codec is to be used. The factors taken into account in selecting a suitable filterbank are normally the sub-band separation, the computational effort required, and the coder delay. A longer impulse response for the filters in the bank will, for example, improve sub-band separation, and so will allow higher compression, but at the expense of additional computational effort and coding delay.

It is an object of the present invention at least to alleviate some of the difficulties of the prior art.

It is a further object of the present invention to provide a method and apparatus for audio coding which is effective over a broader range of applications than has previously been achievable, without the need to reprogram the algorithms and/or replace the filterbank.

It is a further object to provide a method and apparatus which is effective over a range of different sampling rates/bit rates.

According to a first aspect of the present invention there is provided a method of compression of an audio signal including generating or automatically selecting a filterbank in dependence upon sampling frequency or bit rate.

According to a further aspect of the invention there is provided a coder for compressing an audio signal which automatically selects or generates a filterbank in dependence upon sampling frequency or bit rate.

The invention further extends to a codec which includes a coder as previously defined.

The invention is particularly although not exclusively suited to use with transform coders, in which the time-domain audio waveform is converted into a frequency domain representation such as a Fourier, discrete cosine or wavelet transform. The coder may, but need not, be a predictive coder.

The invention finds particular utility in low bit rate applications, for example where an audio signal has to be transmitted across a low bandwidth communications medium such as a telephone or wireless link, a computer network or the Internet. It is particularly useful in situations where the sampling frequency and/or bit rate may either be manually varied by the user or alternatively is automatically varied by the system in accordance with some predefined scheme. For example, where both audio and video data are being transmitted against the same link, the system may automatically apportion the bit budget between the audio and video data-streams to ensure optimum fidelity at the receiving end. Optimum fidelity, in this context, depends very much upon the recipient's perception so that, for example, the audio stream normally has to be given a higher priority from the video stream since it is more irritating for the recipient to receive a broken-up audio signal than a broken-up video signal. As the effective bit rate on the link varies (for example because of noise or congestion), the system may automatically switch to another mode in which the sampling frequency and/or the bit budget assigned to the audio channel changes. In accordance with the present invention, the filter bank in use then automatically adapts to the new conditions, either by regeneration of the filter bank in real time, or alternatively by selection from a predefined plurality of available filterbanks.

The invention may be carried into practice in a number of ways and one specific codec and associated algorithms will now be described, by way of example, with reference to the accompanying drawings, in which:

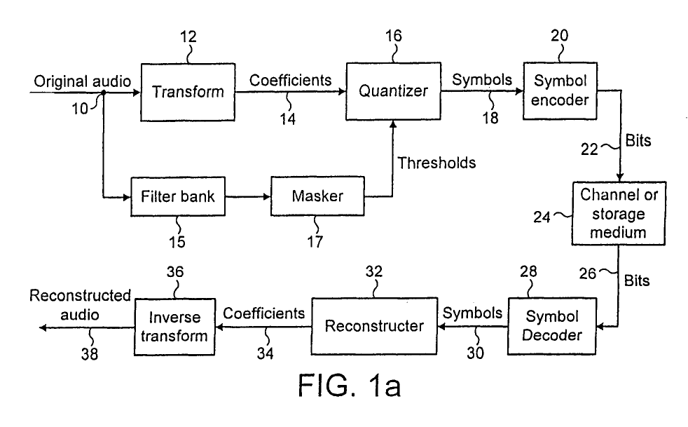

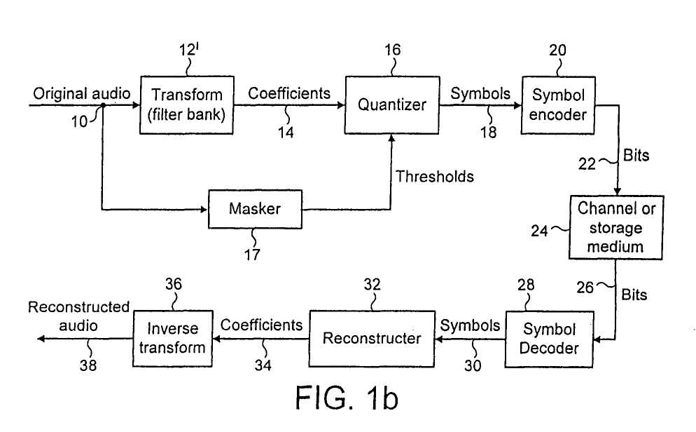

FIG. 1a illustrates schematically a codec according to the one preferred embodiment of the invention;

FIG. 1b illustrates another preferred embodiment; and

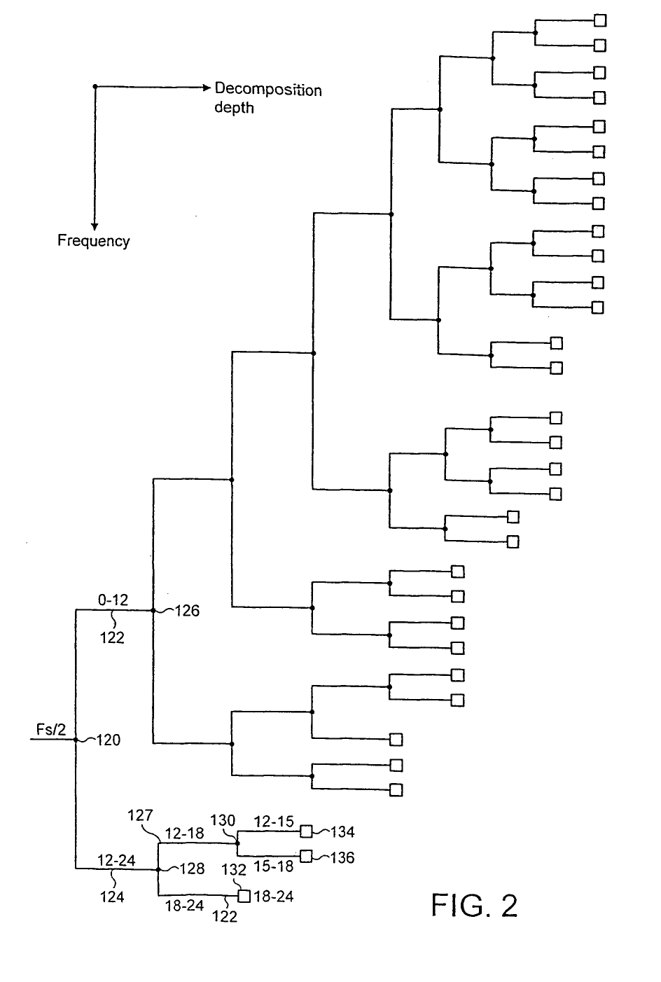

FIG. 2 illustrates the preferred method for constructing the filterbank.

FIG. 1a shows, schematically the preferred codec in accordance with a first embodiment of the invention. The codec shown uses transform coding in which the time-domain audio waveform is converted into a frequency domain representation such as a Fourier, discrete cosine or (preferably) a wavelet transform. Transform coding takes advantage of the fact that the amplitude or envelope of an audio signal changes relatively slowly, and so the coefficients of the transform can be transmitted relatively frequently.

In the codec of FIG. 1a, the boxes 12,16,20 represent a coder, and boxes 28,32,36 a decoder.

The original audio signal 10 is supplied as input to a decorrelating transform 12 which removes redundancy in the signal. The resultant coefficients 14 are then quantized by a quantizer 16 to remove psycho-acoustic redundancy, as will be described in more detail below. This produces a series of symbols 18 which are encoded by a symbol encoder 20 into an output bit-stream 22. The bit-stream is then transmitted via a communications channel or stored, as appropriate, and as indicated by reference numeral 24.

The transmitted or recovered bit-stream 26 is received by a symbol decoder 28 which decodes the bits into symbols 30. These are passed to a reconstructor 32 which reconstructs the coefficients 34, enabling the inverse transform 36 to be applied to produce the reconstructed output audio signal 38. The output signal may not in practice be exactly equivalent to the input signal, since of course the quantization process is irreversible.

The psycho-acoustic response of the human ear is modelled by means of a filterbank 15 which divides the frequency space up into a number of different sub-bands. Each sub-band is dealt with separately, and is quantized with a number of quantized levels obtained from a dynamic bit allocation rule that is controlled by the psycho-acoustic model. Thus, each sub-band has its own masking level, so that masking varies with frequency. The filterbank 15 acts on the audio input 10 to drive a masker 17 which in turn provides masking thresholds for quantizer 16. The transform 12 and the filterbank 15 may, where appropriate, make use of entirely different transform algorithms. Alternatively, they may use the same or similar algorithms, but with different parameters. In the latter case, some of the program code for the transform 12 may be in common with the program code used for the filterbank 15. In one particular arrangement, the transform 12 and the filterbank 15 uses identical or closely similar wavelet transform algorithms, but with different wavelengths. For example, orthogonal wavelets may be used for masking, and symmetric wavelets to produce the coefficients for compression.

A slightly different embodiment is shown in FIG. 1b. This is the same as the embodiment of FIG. 1a, except that the transform 12 and filterbank 15 are combined into a single block, marked with the reference numeral 12′. In this embodiment, the transform and the filterbank are essentially one and the same, with the common transform 12′ providing both coefficients to the quantizer 16 and also to the masker 17.

Alternatively, the masker 17 could instead represent some psychoacoustic model, for example, the standard model used in MP3.

In contrast with the prior art, the filterbank used in the present invention is not predefined and fixed but instead automatically adapts itself to the sampling frequency/bit rate in use. The preferred approach is to use Wavelet Packet decomposition—that is an arbitrary sub-band decomposition tree which represents a generalisation of the standard wavelet transform decomposition. In a normal wavelet transform, only the low-pass sub-band at a particular scale is further decomposed: this works well in some cases, especially with image compression, but often the time-frequency characteristics of the signal may not match the time-frequency localisations offered by the wavelet, which can result in inefficient decomposition. Wavelet Packet decomposition is more flexible, in that different scales can be applied to different frequency ranges, thereby allowing quite efficient modelling of the psycho-acoustic model that is being used.

FIG. 2 illustrates an exemplary Wavelet Packet decomposition which models the critical bands of the human auditory system. Each open square represents a specific frequency sub-band which will normally have a width which is less than that of the corresponding critical band which corresponds to the frequency at the centre of the sub-band. In that way, the frequency spectrum is selectively divided up into enough sub-bands, of widths varying with frequency, so that no sub-band is of greater width than its corresponding critical band. That should ensure that quantization and other noise within each sub-band can be effectively masked.

In the illustrative example of FIG. 2, the overall frequency range runs from 0 to 24 kHz. The root of the tree 120 is therefore at 12 kHz, and this defines a node which the tree splits into two branches, the first 122 covering the 0 to 12 kHz range, and the second 124 covering the 12 to 24 kHz range. Each of these two branches are then split again at nodes 126, 128, the latter of which defines two sub-branches 127,130 which cover the bands 12 to 18 kHz and 18 to 24 kHz respectively. The branch 127 ends in a node 130 which defines two further sub-branches, namely the 12 to 15 kHz sub-band and the 15 to 18 kHz sub-band. These end respectively in “leaves” 134, 136. The branch 130 ends in a higher-level leaf 132.

Decomposition of the tree at each node continues until each leaf defines a sub-band which is narrower than the critical band corresponding to the centre frequency. For example, it is known from the psycho-acoustic model that the critical band for the leaf 132 (at 21 kHz, which is the centre-point of the band, 18 to 24 kHz) is wider than 18 to 24 kHz. Likewise, the critical band for the leaf 136 (at 16.5 kHz, the centre of the band) is greater than 15 to 18 kHz.

There are a number of ways in which such a tree can be calculated, but the preferred approach is to construct the tree systematically from the lower to the higher frequencies. Starting at the first level, the sampling frequency is divided by two, to define the root node 120. This defines two bands of equal frequency on either side of the node (represented in the drawing by the branches 122, 124). Taking the lower of the two bands, the central frequency 126 is determined, effectively dividing that band up into two further sub-bands. The process is repeated at each successive level. When one arrives a leaf which has a width less than or equal to the critical bandwidth, band splitting can cease at that level; one then moves to the next level starting again at the lower frequency band. When the lowest frequency band has a width less than or equal to its critical bandwidth, the decomposition is complete.

Since the critical bands are known to be monotonic increasing with frequency, the algorithm knows that if N levels are needed at a given frequency, there must be N or fewer levels required for all higher frequencies.

The method described above guarantees that, for any sampling frequency, all the sub-band widths are equal to or less than the widths of the corresponding critical bands.

It will of course be understood that the system needs information on which the critical bands actually are, for each frequency, so that it knows when to stop the decomposition. That information—derived from psycho-acoustical experimentation—may either be stored within a look-up table or may be approximated as needed at run-time. The following approximate formula may be used for that purpose, where BW represents the critical bandwidth in Hz and f the centre frequency of the band:

BW=25+75[1+1.4f²]^{0.69}

In a variation of the method described above, the user may control the “strictness” or otherwise of the algorithm by means of a user-defined constant Konst. The number of scales (level of decomposition) is chosen as the smallest for which the width of the sub-band multiplied by Konst is smaller than the critical band width at the centre frequency of the sub-band. Konst=1 corresponds to the method described above: Konst>1 defines a higher specification which generates more sub-bands; and Konst<1 is more lax, and allows the sub-bands to be rather broader than the critical bands.

The preferred algorithm for generating the tree of FIG. 2 is set out below. The array ToDo records how many decompositions need to be carried out at each level. The decompositions start a low frequency and continue until the sub-band width is small enough. Higher frequencies do not need further splits since the critical bandwidth is monotonic increasing with frequency:

```
Konst = 1
MaxLevs = 9;
Nyq = Fs/2;
ToDo = zeros (1,MaxLevs);
Widths = ToDo;
InBands = ToDo;
Bands = 1;
for Lev = 1:MaxLevs
  BW = Fs/(2\hat{ }(Lev) ) ;
  Widths (Lev) = BW/2;
  CF=BW/2;
  CritBW=CritFn (CF);
  KBW = Konst*BW;
  while (CritBW < KBW) & (CF < Nyq)
    ToDo (Lev) = ToDo (Lev)+1;
    Bands = Bands + 1;
    CF = CF + BW;
    CritBW=CritFn (CF);
  end % (of counting the decompositions at this level)
end % (of computing the decomposition)
```

It will be understood of course that the above is merely exemplary, and that the tree could be constructed in any convenient way.

The tree is created automatically at run-time, and automatically adapts itself to changes in the sampling frequency/bit rate by re-computing as necessary. Alternatively (although it is not preferred) a series of possible trees could be calculated in advance for different sampling frequencies/bit rates, and those could be stored within the coder. The appropriate pre-compiled tree could then be selected automatically by the system in dependence upon the sampling frequency/bit rate.

Masking and compression are preferably both carried out using the same transform, for example a wavelet transform. While the system operates well with the same wavelet being used at each level, and it would be possible to specify differing filters to be used at each level or at different frequencies. For example, one may wish to use a shorter wavelet at lower levels to reduce delay.

For the filterbank to be effective in providing input to the masker, an orthogonal wavelet should be used, such as the Daubechies wavelet, because only with orthogonal wavelets can the power in the bands be calculated accurately. However it is well known that orthogonal wavelets cannot be symmetric, and the Daubechies wavelets are highly asymmetric. For compression it is best to use a symmetric wavelet because quantization in combination with a non-symmetric wavelet will produce phase distortion which is quite noticeable to human listeners. In practice it has been found that if it is desired that the same wavelet transform (e.g. as in FIG. 1b) is to be used for masking and compression, so-called ‘Symlets’ are a good compromise, as they are the most symmetric orthogonal wavelets. Alternatively the filterbank can be used twice, once with orthogonal wavelets for masking, and again with a symmetric wavelet to produce the coefficients for compression (e.g. as in FIG. 1a).

If non-orthogonal wavelets are used, it has been found that good results can be achieved with a Konst value of around 1.2.

To avoid producing artefacts due to block boundaries, the audio signal is preferably treated as one infinite block, with the wavelet filter simply being “slid” along the signal.

The preferred method and apparatus of the invention may be integrated within a video codec, for simultaneous transmission of images and audio.

1. A method of compression of an audio signal including generating or automatically selecting a filterbank in dependence upon sampling frequency or bit rate.

2. A method as claimed in claim 1 in which the filterbank is automatically updated, in use, as the sampling frequency or bit rate changes.

3. A method as claimed in claim 1 or claim 2 in which the filterbank is generated by means of a tree structure.

4. A method as claimed in claim 3 in which the tree structure is a binary tree.

5. A method as claimed in claim 3 or claim 4 in which the tree is constructed by defining a trial band at level one, comparing the trial band with a corresponding critical band, and splitting the trial band if the trial band is determined to be too broad.

6. A method as claimed in claim 5 in which the trial band is determined to be too broad if it is broader than the corresponding critical band.

7. A method as claimed in claim 5 in which the trial band is determined to be too broad if the width of the band multiplied by a constant is larger than the width of the corresponding critical band; or if the width of the band is larger than the width of the corresponding critical band multiplied by a constant.

8. A method as claimed in any one of claims 5 to 7 in which the critical band corresponding to a trial band is that critical band which is centred on the central frequency of the trial band.

9. A method as claimed in any one of claims 5 to 8 in which the critical bands are stored in a look-up table.

10. A method as claimed in any one of claims 5 to 8 in which the critical bands are approximated, as required, by a deterministic formula.

11. A method as claimed in any one of the preceding claims in which the filterbank is used to define the masking to be applied to the signal.

12. A method as claimed in claim 11 in which the same transform is used both for compression and masking.

13. A method as claimed in claim 12 in which the transform is a wavelet transform.

14. A method as claimed in claim 11 in which masking is determined by means of a wave let transform.

15. A method as claimed in claim 14 in which the wavelet transform uses the same wavelet at all scales.

16. A method as claimed in claim 14 in which the wavelet transform uses different wavelets at different scales.

17. A coder for compressing an audio signal which automatically selects or generates a filterbank in dependence upon sampling frequency or bit rate.

18. A codec including a coder as claimed in claim 17.
